(19) United States
(12) Patent Application Publication
(10) Pub. No.: US 2019/0045644 A1
(43) Pub. Date: Feb. 7, 2019

(54) VENTILATION COVER APPARATUS FOR AN ELECTRICAL ENCLOSURE INCLUDING WATER-RESISTANT AND ARC-RESISTANT FEATURES

(71) Applicant: GENERAL ELECTRIC COMPANY, Schenectady, NY (US)

(72) Inventors: Xuhui REN, ShangHai (CN); Yu LU, ShangHai (CN); Wei WANG, ShangHai (CN)

(21) Appl. No.: 15/985,845

(22) Filed: May 22, 2018

(30) Foreign Application Priority Data
Aug. 7, 2017 (CN) 201710666466.9

(51) Int. Cl. H05K 5/02; H02B 1/56; H05K 7/20

(52) U.S. Cl. CPC H05K 5/0213; H05K 7/20127; H02B 1/565

(57) ABSTRACT

An electrical enclosure includes a plurality of exterior panels defining a volume and an enclosure ventilation assembly adjacent to the volume. The enclosure ventilation assembly includes a ventilation panel including a ventilation aperture defined therethrough, a ventilation cover assembly, and an arc shield assembly. The ventilation cover assembly is coupled to the ventilation panel to cover the ventilation aperture and is configured to allow gasses into the electrical enclosure through the ventilation aperture, to inhibit an intrusion of water into the electrical enclosure, and to inhibit egress of an arc fault discharge from the enclosure. The arc shield assembly includes an arc shield rotatably coupled to the enclosure ventilation assembly and configured to rotate between a first, open position and a second, closed position, wherein the first, open position facilitates a flow of gasses into the electrical enclosure and the second, closed position inhibits an arc fault discharge egress.

### BACKGROUND

The field of the disclosure relates generally to ventilation apparatus for electrical enclosures, and, more specifically, to a ventilation cover assembly, an arc shield assembly, and systems and methods thereof to provide air flow to an electrical enclosure while inhibiting water infiltration and an arc fault discharge egress.

Known electrical enclosures with switchgear equipment include multiple compartments including a line or busbar portion and a load or circuit breaker portion. The busbar portion includes at least one busbar coupled to an electrical load through voltage line terminals. Circuit breakers enable interruption of electrical current flow to connected loads. Devices inside known electrical enclosures such as busbars, circuit breakers, and voltage line terminals generate heat during operation. Such known electrical enclosures also include covered vents on exterior panels to allow exterior air from the environment to enter the electrical enclosure for cooling purposes and to inhibit accumulation of hazardous gas fumes while inhibiting water and debris entry into the enclosure. Air exchange with the exterior environment facilitates safe operation of such known electrical enclosures.

During operation and maintenance activities of at least some known electrical enclosures, cooling requirements and electrical arc faults are additional safety and reliability considerations. Various standards exist, including from standard-making bodies such as the Institute of Electrical and Electronic Engineers (IEEE), which state that compartments of electrical enclosures be separated from an external environment by solid walls or by ventilated covers with specifically sized openings. Such standards are meant to mitigate risk to operational continuity and safety of operators, maintenance personnel, bystanders, and property from arc faults, but they complicate effective air exchange between electronic components and an external environment and may reduce cooling in known electrical enclosures.

### BRIEF DESCRIPTION

In one aspect, an electrical enclosure is provided. The electrical enclosure includes a plurality of exterior panels defining a volume and an enclosure ventilation assembly adjacent the volume. The enclosure ventilation assembly includes a ventilation panel including a ventilation aperture defined therethrough, a ventilation cover assembly, and an arc shield assembly. The ventilation cover assembly is coupled to the ventilation panel to cover the ventilation aperture and is configured to allow a flow of gasses into the electrical enclosure through the ventilation aperture, to inhibit an intrusion of water into the electrical enclosure, and to inhibit egress of an arc fault discharge from the electrical enclosure. The arc shield assembly includes an arc shield rotatably coupled to the enclosure ventilation assembly and configured to rotate between a first, open position and a second, closed position, wherein the first, open position facilitates a flow of gasses into the electrical enclosure through the ventilation aperture and the second, closed position inhibits an arc fault discharge egress from the electrical enclosure.

In another aspect, a ventilation cover assembly configured to cover a ventilation aperture in an electrical enclosure is provided. The ventilation cover assembly includes a ventilated cover and at least one internal barrier. The ventilated cover includes a front wall, a pair of sidewalls, a top wall, and a bottom wall. The front wall includes an upper portion and a lower portion, the lower portion including a plurality of ventilation openings. Each of the pair of sidewalls is coupled to the front wall on opposite edges of the front wall and extends in a first direction perpendicular to the front wall. The top wall and the bottom wall are joined to the front wall on opposite edges and extend in the first direction, each of the top wall and the bottom wall joined to each of the pair of sidewalls. The at least one internal barrier is coupled within the ventilated cover and is displaced from the front wall in the first direction.

In yet another aspect, an arc shield assembly for an electrical enclosure is provided. The arc shield assembly includes an arc shield and a closing mechanism. The arc shield is rotatably coupled to the electrical enclosure and is configured to rotate between a first, open position and a second, closed position, wherein the first, open position facilitates a flow of gases through the electrical enclosure and the second, closed position inhibits a flow of gases through the arc shield assembly. The closing mechanism includes a linkage arm coupled to the arc shield and a biasing member coupled to the linkage arm and configured to cause the arc shield to rotate to the second, closed position during an arc fault.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 is a side and partial cutaway view of an example embodiment of an electrical enclosure;

FIG. 2 is an exploded side and partial cutaway view of an example embodiment of an enclosure ventilation assembly that may be used with the electrical enclosure shown in FIG. 1;

FIG. 3 is a perspective exploded view of the ventilation cover assembly shown in FIG. 2;

FIG. 4 is a side and partial cutaway view of the enclosure ventilation assembly shown in FIG. 2; and

FIG. 5 is a flowchart of an example method of assembling a ventilation cover assembly that may be used with the electrical enclosure shown in FIG. 1.

Unless otherwise indicated, the drawings provided herein are meant to illustrate features of embodiments of the disclosure. These features are believed to be applicable in a wide variety of systems including one or more embodiments of the disclosure. As such, the drawings are not meant to include all conventional features known by those of ordinary skill in the art to be required for the practice of the embodiments disclosed herein.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “substantially,” and “approximately,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

The ventilation devices and associated systems and methods thereof described herein are suited to facilitate air-exchange between an external environment and the interior of electrical enclosures while inhibiting water infiltration. The ventilation devices, associated systems, and methods thereof described herein are further suited to facilitate safe and continuous operation of the components within the electrical enclosures because of the heat exchange associated with ventilation of the enclosure. The systems and methods described herein are also suited to inhibit egress of an electrical arc fault discharge arising from arc faults occurring inside of electrical enclosures. The ventilation devices and associated systems and methods thereof described herein are further suited to meet electrical enclosure construction and operation standards from, for example, Institute of Electrical and Electronics Engineers (IEEE), by facilitating airflow into the enclosure while inhibiting water infiltration and an arc fault discharge egress from the enclosure.

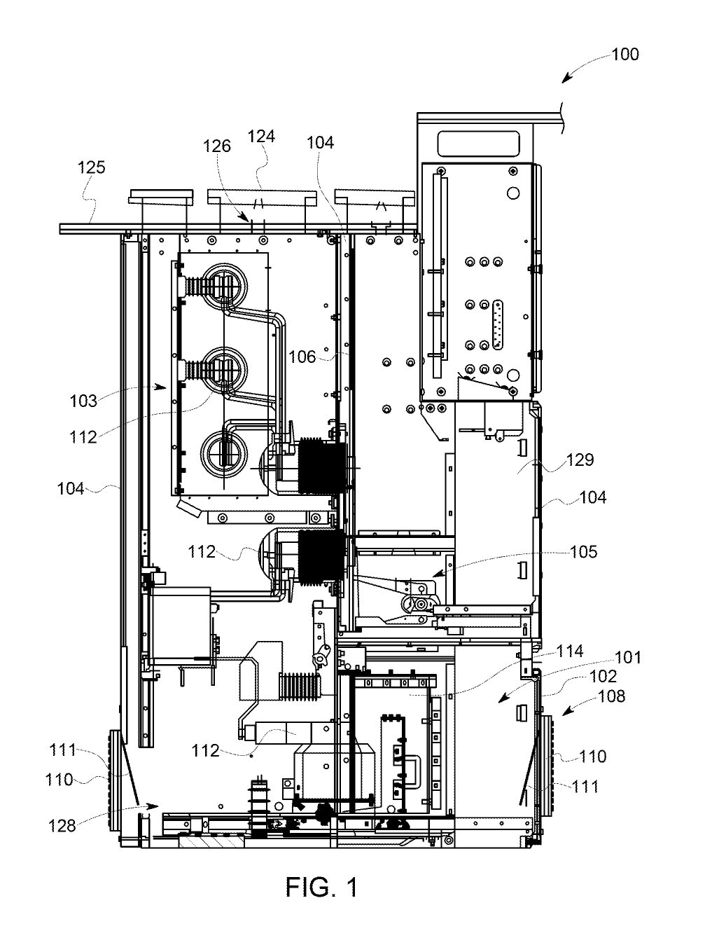

FIG. 1 is a side and partial cutaway view of an example embodiment of an electrical enclosure, for example electrical enclosure 100. In the example embodiment, electrical enclosure 100 includes at least one breaker compartment 101 and at least one cable compartment 103. Each breaker compartment 101 includes at least one door 102, including an opening 107 defined therethrough, which allows access to an interior of electrical enclosure 100, for example to an arc protection system 105. In the example embodiment, an arc protection system 105 is configured to facilitate extinguishing an arc generated during an arc fault in breaker compartment 101 or cable compartment 103. An arc fault is a type of electrical explosion or discharge that results from a low-impedance connection through air to a ground or another voltage phase in an electrical system. In the exemplary embodiment, an arc fault discharge includes, but is not limited to, arc blast, arc gasses, plasma, pressure waves, and debris from the arc blast.

In the exemplary embodiment, electrical enclosure 100 also includes a plurality of exterior panels 104, arranged upon and coupled to a plurality of supportive frame members 106, which provide structural support and protection from conditions present in an external environment outside electrical enclosure 100. In the example embodiment, plurality of exterior panels 104 are metal or metal-clad panels. Also, in the example embodiment, an enclosure ventilation assembly 108 includes door 102, a ventilation cover assembly 110 sized and shaped to be received in opening 107, and an arc shield assembly 111. In alternative embodiments, opening 107 may be defined in any component, including exterior panel 104, that enables electrical enclosure 100 to function as described herein.

In the example embodiment, ventilation cover assembly 110 facilitates exchange of air from an external environment to/from the interior of electrical enclosure 100 and further facilitates inhibition of accumulation of fumes therein. Arc shield assembly 111 inhibits the egress of an arc fault discharge generated during an electrical arc fault inside electrical enclosure 100. Also, in the example embodiment, interior of electrical enclosure 100 includes a plurality of electrical components 112 such as electrical lines, switchgear, switches, connectors, and various other devices necessary to connect electrical load devices to main power lines and circuit breakers. Further, in the example embodiment, interior of electrical enclosure 100 includes one or more interior panels 114.

Furthermore, in the example embodiment, electrical enclosure 100 includes at least one flap 124 coupled to a top panel 125 of electrical enclosure 100. Each flap 124 covers at least one panel aperture 126 defined through top panel 125. Flaps 124 are configured to expel heat, fumes, arc plasma, gases, and pressure from, and facilitate a general abatement of undesirable physical conditions within, electrical enclosure 100 which arise in the event of an electrical arc fault therein. As such, flaps 124 are embodied in rectangular panels coupled to top panel 125 so as to remain in a closed position covering panel aperture 126 during normal operating conditions of electrical enclosure 100. Moreover, in the example embodiment, flaps 124 are rotatably coupled to top panel 125 including, without limitation, through a hinge on one of four sides of flap 124. Upon a rapid buildup of pressure within the interior of electrical enclosure 100 (i.e., during an arc fault), a force originating in a bottom portion 128 of electrical enclosure 100 near arc protection system 105 is exerted upon undersides of flaps 124 to uncover panel apertures 126 to facilitate at least one of expulsion of hot gases from electrical enclosure 100, reduction of pressure within electrical enclosure 100, and equilibration of pressure within electrical enclosure 100.

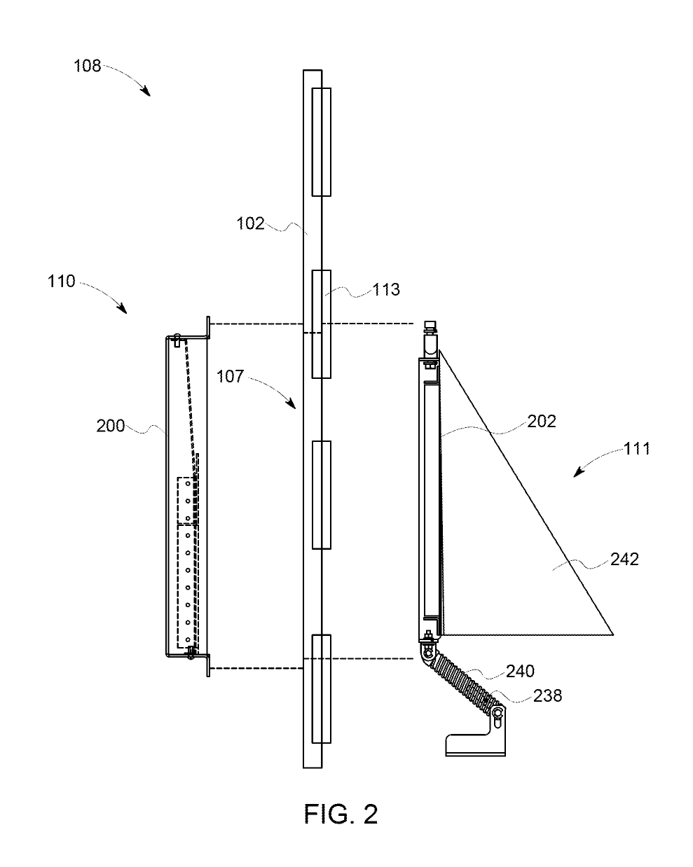

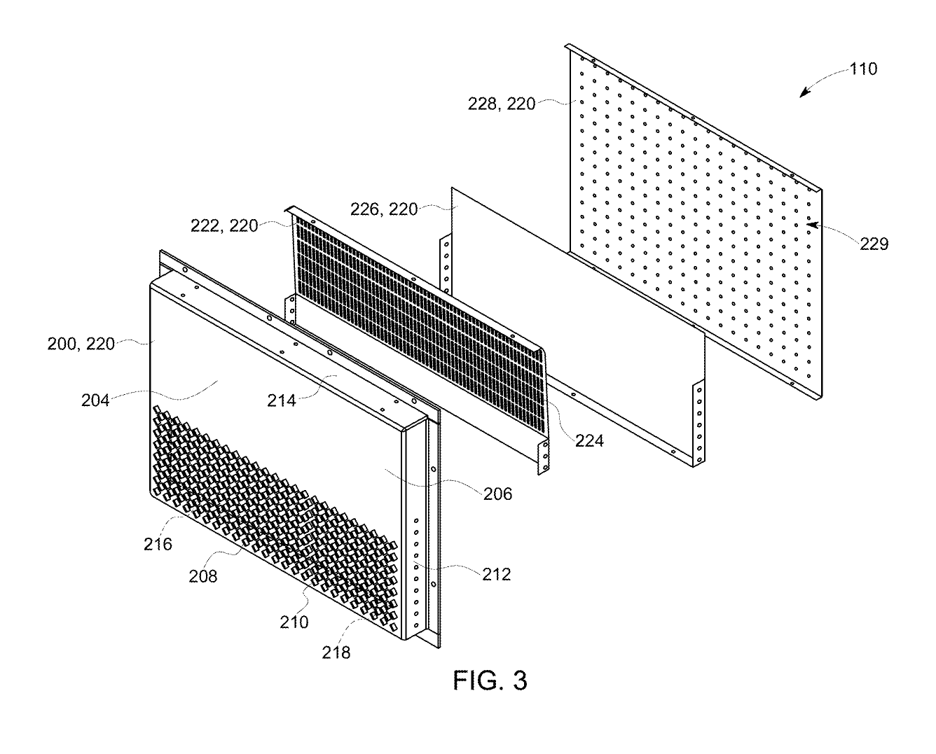

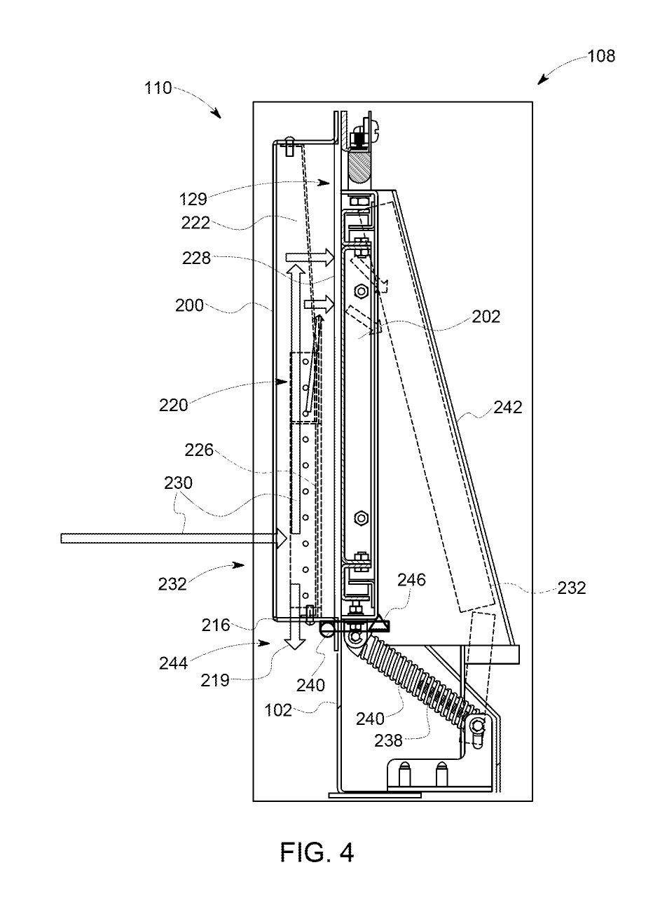

FIG. 2 is an exploded side and partial cutaway view of an example embodiment of enclosure ventilation assembly 108 that may be used with electrical enclosure 100 shown in FIG. 1. In the example embodiment, enclosure ventilation assembly 108 includes door 102 including a plurality of door hinges 113. In alternative embodiments, enclosure ventilation assembly 108 may include exterior panel 104 or any combination of exterior panels 104 and doors 102. In the example embodiment, ventilation cover assembly 110 is coupled to door 102 and arc shield assembly 111. Arc shield assembly 111 is coupled to door 102 and ventilation cover assembly 110. In the example embodiment, ventilation cover assembly 110 is configured to allow a flow of gasses into electrical enclosure 100 through door 102, to inhibit an intrusion of water into electrical enclosure 100, and to inhibit the egress of an arc fault discharge from electrical enclosure 100. Arc shield assembly is configured to allow gas exchange between an external environment and the interior of electrical enclosure 100, and to further inhibit the egress of the arc fault discharge from electrical enclosure 100. In the example embodiment, ventilation cover assembly 110 includes a ventilated cover 200 (shown in FIGS. 3 and 4) and arc shield assembly 111 includes an arc shield 202. In alternative embodiments, ventilation cover assembly 110 and arc shield assembly 111 include any components that enable enclosure ventilation assembly 108 to function as described herein.

FIG. 3 is a perspective assembly view of example ventilation cover assembly 110 (shown in FIG. 2). With reference to FIG. 3, in the example embodiment, ventilated cover 200 includes a front wall 204 including an upper portion 206 and a lower portion 208. Lower portion 208 includes a plurality of ventilation openings 210 configured to facilitate air flow through lower portion 208. In the example embodiment, each ventilation opening 210 is a circular opening with a diameter of 12 mm. In another suitable embodiment, each ventilation opening 210 is a 12 mm by 12 mm rectangular opening. In alternative embodiments, ventilation openings 210 are configured in any manner that enables ventilated cover 200 to operate as described herein. Ventilated cover 200 also includes a pair of sidewalls 212 coupled to front wall 204 on opposite edges of front wall 204 and extending in a first direction perpendicular to front wall 204. In one embodiment, sidewalls 212 are solid sidewalls. Ventilated cover 200 further includes a top wall 214 and a bottom wall 216 coupled to front wall 204 on opposite edges and extending in the first direction perpendicular to front wall 204. Each of top wall 214 and bottom wall 216 are also coupled to sidewalls 212. Bottom wall 216 includes a plurality of drainage openings 218 configured to enable water to drain through bottom wall 216 to external environment following drainage path 219. In alternative embodiments, ventilated cover 200 is configured to facilitate gas exchange between electrical enclosure 100 and an external environment in any manner that enables ventilation cover assembly 110 to operate as described herein.

In the example embodiment, ventilation cover assembly 110 includes a plurality of internal barriers 220 coupled within ventilated cover 200 and displaced from front wall 204. In the example embodiment, plurality of internal barriers 220 includes an upper internal barrier 222, a lower barrier 226, and a particulate barrier 228. In one embodiment, lower barrier 226 is a solid lower barrier. Upper internal barrier 222 includes a plurality of ventilation openings 224 configured to facilitate gas exchange through upper internal barrier 222. Lower barrier 226 is displaced from upper internal barrier 222 and is configured to form a barrier to water intrusion through ventilation cover assembly 110. A ventilation path 230 is defined through ventilation cover assembly 110 between ventilated cover 200, upper internal barrier 222, lower barrier 226, and particulate barrier 228.

Particulate barrier 228 is displaced from lower barrier 226 and is coupled to each of sidewalls 212, top wall 214, and bottom wall 216. Particulate barrier 228 includes a plurality of ventilation openings 229 spaced evenly across the face of particulate barrier 228 and configured to further inhibit the ingress of water through ventilation cover assembly 110 to electrical enclosure 100. In the example embodiment, each ventilation opening 229 is a circular opening with a diameter of 1 mm. In other suitable embodiments, ventilation openings 229 are shaped and configured in any manner that enables operation of ventilation cover assembly 110 as described herein. In alternative embodiments, ventilation cover assembly 110 includes any type and quantity of internal barriers 220 as enables ventilation cover assembly 110 to operate as described herein.

In the example embodiment, plurality of internal barriers 220 are configured to define a ventilation path 230 between plurality of internal barriers 220 and ventilation cover assembly 110. More specifically, plurality of internal barriers 220 are arranged such that fluid and gasses entering ventilation cover assembly 110 from an external environment and from within electrical enclosure 100 are not able to follow a straight-line path to pass through ventilation cover assembly 110. Ventilation path 230 also inhibits an arc fault discharge from following a straight-line path to exit electrical enclosure 100, increasing safety of electrical enclosure 100. In alternative embodiments, internal barriers 220 are arranged and configured in any manner that enables ventilation cover assembly 110 to operate as described herein.

FIG. 4 is a side and partial cutaway view of enclosure ventilation assembly 108 (shown in FIG. 2). With reference to FIGS. 3-4, in the example embodiment, arc shield assembly 111 includes an arc shield 202 rotatably coupled to ventilation cover assembly 110. Arc shield 202 is configured to rotate between a first, open position 232 and a second, closed position 234, wherein first position 232 facilitates a flow of gasses through ventilation cover assembly 110 and second position 234 inhibits a flow of gasses through ventilation cover assembly 110. In the example embodiment, arc shield 202 is flush against the surface of at least a portion of ventilated cover 200 when arc shield 202 is in second position 234 and rotated away from at least a portion of ventilated cover 200 when arc shield 202 is in first position 232. In alternative embodiments, arc shield 202 may be configured to facilitate or inhibit a flow of gasses through ventilation cover assembly 110 in any manner that enables ventilation cover assembly 110 and arc shield assembly 111 to operate as described herein.

In the example embodiment, arc shield assembly 111 includes at least one closing mechanism 236 including a linkage arm 238 and a biasing member 240. Linkage arm 238 is rotatably coupled to arc shield 202. Biasing member 240 is coupled to linkage arm 238 and is configured to cause arc shield 202 to rotate from first position 232 to second position 234 in response to an arc fault. In the example embodiment, biasing member 240 is a spring. In alternative embodiments, biasing member 240 is any component that enables operation of arc shield 202 as described herein. In the example embodiment, linkage arm 238 is also rotatably coupled to door 102. In alternative embodiments, linkage arm 238 is rotatably coupled to any component of electrical enclosure 100 that enables arc shield assembly 111 to operate as described herein.

In the example embodiment, arc shield assembly 111 also includes a pair of arc shield side retainer plates 242. Arc shield side retainer plates 242 and biasing member 240 are configured to cooperate with biasing member 240 and linkage arm 238 to retain arc shield 202 in first position 232 during operation of electrical components 112 within electrical enclosure 100, absent an arc fault. Arc shield plates 242 and biasing member 240 are also configured to cooperate to retain arc shield 202 in second position 234 during an arc fault. In the example embodiment, arc shield side retainer plates 242 are coupled to ventilation cover assembly 110 adjacent to arc shield 202 and facilitate inhibiting an arc fault discharge from dislocating arc shield 202 from second position 234 by inhibiting a flow of the arc fault discharge from contacting at least two sides of arc shield 202. In alternative embodiments arc shield plates are coupled to ventilation cover assembly 110 in any location that enables ventilation cover assembly 110 and arc shield assembly 111 to operate as described herein.

In the example embodiment, when arc shield 202 is in first position 232, linkage arm 238 is positioned at an acute angle relative to the horizontal dimension of enclosure ventilation assembly 108 and biasing member 240 is compressed relative to its resting length. In first position 232, biasing member 240 exerts force against arc shield 202 to facilitate retaining arc shield 202 against pair of arc shield side retainer plates 242. In the occurrence of an arc fault, arc shield 202 is caused to rotate by the arc fault discharge such that linkage arm 238 rotates to an obtuse angle relative to the horizontal dimension of enclosure ventilation assembly 108. When linkage arm 238 is at an obtuse angle relative to the horizontal dimension of enclosure ventilation assembly 108, biasing member 240 exerts a force on arc shield 202 to cause arc shield 202 to move towards second position 234. In alternative embodiments, linkage arm 238 and biasing member 240 are configured in any way that enables arc shield assembly 111 to operate as described herein.

In the example embodiment, arc shield assembly 111 includes an arc shield locking mechanism 244. Arc shield locking mechanism 244 is configured to releasably retain arc shield 202 in second position 234. Arc shield locking mechanism 244 includes locking arm 246 and locking arm biasing member 248. Locking arm 246 is shaped and configured to receive arc shield 202 as arc shield 202 travels from first position 232 to second position 234. Locking arm 246 is rotatably coupled to ventilation cover assembly 110 and locking arm biasing member 248 is coupled between ventilation cover assembly 110 and locking arm 246 such that locking arm 246 is able to snap over arc shield 202 and retain arc shield 202 in first position 232. Once arc shield 202 has been retained by locking arm 246, locking arm 246 may be depressed to counteract locking arm biasing member 248 and release arc shield 202. In alternative embodiments locking arm 246 and locking arm biasing member 248 are configured in any manner that enables operation of arc shield assembly 111 as described herein.

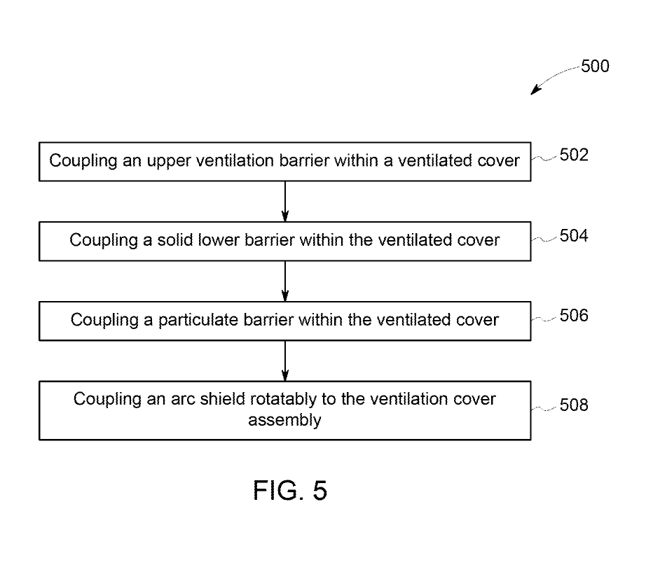

FIG. 5 is a flowchart of an example method of assembling a ventilation cover assembly that may be used with the electrical enclosure shown in FIG. 1. Method 500 includes coupling 502 an upper internal barrier, for example upper internal barrier 222, within a ventilated cover, for example ventilated cover 200. Ventilated cover 200 includes a front wall, for example front wall 204, front wall 204 having an upper portion, for example upper portion 206, and a lower portion, for example lower portion 208. Upper portion 206 is solid, and lower portion 208 includes a plurality of ventilation openings, for example ventilation openings 210, as shown and described above with respect to FIGS. 1-4. Ventilated cover 200 also includes a top wall, for example top wall 214, a pair of sidewalls, for example sidewalls 212, and a bottom wall including drainage openings, for example bottom wall 216 and drainage openings 218, as shown and described above with respect to FIGS. 1-4. Upper internal barrier 222 is displaced from front wall 204 and includes a plurality of ventilation openings, for example ventilation openings 224, as shown and described above with respect to FIGS. 1-4.

Also in the example embodiment, method 500 includes coupling 504 a lower barrier, for example lower barrier 226, within ventilated cover 200. Lower barrier 226 is displaced from upper internal barrier 222 and is coupled to at least one of sidewalls 212, bottom wall 216, and top wall 214, as shown and described above with respect to FIGS. 1-4. Method 500 also includes coupling 506 a particulate barrier, for example particulate barrier 228, within ventilated cover 200. Particulate barrier 228 is displaced from lower barrier 226 and includes a plurality of ventilation openings, as shown and described above with respect to FIGS. 1-4. Particulate barrier 228 is coupled to each of sidewalls 212, bottom wall 216, and top wall 214. Method 500 further includes coupling 508 an arc shield, for instance arc shield 202, rotatably to a ventilation cover assembly, for instance to ventilation cover assembly 110, to form an enclosure ventilation assembly, as shown and described above with respect to FIGS. 1-4. A linkage arm, for instance linkage arm 238, is coupled between arc shield 202 and ventilation cover assembly 110 and is acted upon by a biasing member, for instance biasing member 240, to assist moving arc shield 202 from a first position, for instance first position 232, to a second position, for instance second position 234, as shown and described above with respect to FIGS. 1-4. As a consequence of steps 502, 504, 506, and 508, a ventilation flow path is defined through the ventilated cover, while a path for water to pass through the ventilated cover is not present. Additionally, egress of an arc fault discharge through the ventilated cover is prevented by the arc shield. Method 500 facilitates assembly of enclosure ventilation assembly 108 into electrical enclosures 100. Electrical enclosures such as electrical enclosure 100 are assembled with enclosure ventilation assembly 108 during fabrication, i.e., manufacture, thereof It is also possible to assemble enclosure ventilation assemblies 108 into pre-existing electrical enclosures 100 with minor modifications, i.e., retrofitting. For example, a suitably-sized opening may be cut into door 102 or exterior panel 104 of an existing electrical enclosure 100, as described above with reference to FIG. 1.

The above described ventilation cover assemblies, arc shield assemblies, and associated systems and methods thereof are suited to facilitate air-exchange between an external environment and the interior of electrical enclosures while inhibiting water infiltration. The ventilation cover assemblies, arc shield assemblies, and associated systems and methods are further suited to facilitate safe and continuous operation of the components within the electrical enclosures because of the heat exchange due to the enclosure ventilation. The systems and methods are also suited to inhibit egress of an arc fault discharge arising from arc faults occurring inside of electrical enclosures. The ventilation cover assemblies, arc shield assemblies, and associated systems and methods are further suited to meet electrical enclosure construction and operation standards from, for example, Institute of Electrical and Electronics Engineers (IEEE), by facilitating airflow into the enclosure while inhibiting water infiltration and an arc fault discharge egress from the enclosure.

An example technical effect of the methods, systems, and apparatus described herein includes at least one of (a) facilitating air-exchange between an external environment and the interior of an electrical enclosure; (b) inhibiting water from entering the electrical enclosure; (c) facilitating safe and continuous operation of the components within the enclosure because of heat exchange with an external environment; (d) rapidly inhibiting egress of an electrical arc fault discharge; and (e) increasing the internal arc classification rating of low-, medium-, and high-voltage switchgear in both DC and AC power systems applications.

Example embodiments of ventilation cover assemblies, arc shield assemblies, and methods of assembling ventilation devices are described above in detail. The ventilation cover assemblies, arc shield assemblies, and methods are not limited to the specific embodiments described herein but, rather, components of the ventilation cover assemblies, arc shield assemblies, and/or operations of the methods may be utilized independently and separately from other components and/or operations described herein. Further, the described components and/or operations may also be defined in, or used in combination with, other systems, methods, and/or assemblies, and are not limited to practice with only the ventilation cover assemblies, arc shield assemblies, and electrical enclosures described herein.

The order of execution or performance of the operations in the embodiments of the disclosure illustrated and described herein is not essential, unless otherwise specified. That is, the operations may be performed in any order, unless otherwise specified, and embodiments of the disclosure may include additional or fewer operations than those disclosed herein. For example, it is contemplated that executing or performing a particular operation before, contemporaneously with, or after another operation is within the scope of aspects of the disclosure.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to disclose the disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. An electrical enclosure comprising:
a plurality of exterior panels defining a volume; and
an enclosure ventilation assembly adjacent the volume, said enclosure ventilation assembly comprising:
a ventilation panel including a ventilation aperture defined therethrough;
a ventilation cover assembly coupled to said ventilation panel to cover the ventilation aperture and configured to allow a flow of gasses into said electrical enclosure through the ventilation aperture, and to inhibit egress of an arc fault discharge from said electrical enclosure; and
an arc shield assembly including an arc shield rotatably coupled to said enclosure ventilation assembly and configured to rotate between a first, open position and a second, closed position, wherein said first, open position facilitates a flow of gasses into said electrical enclosure through the ventilation aperture and said second, closed position inhibits an arc fault discharge egress from said electrical enclosure.

2. An electrical enclosure in accordance with claim 1, wherein said ventilation panel comprises a door coupled to said electrical enclosure.

3. An electrical enclosure in accordance with claim 1, wherein said ventilation cover assembly comprises:
a ventilated cover comprising:
a front wall including an upper portion and a lower portion, said lower portion including a plurality of ventilation openings;
a pair of sidewalls coupled to said front wall on opposite edges of said front wall and extending in a first direction perpendicular to said front wall; and
a top wall and a bottom wall joined to said front wall on opposite edges and extending in the first direction, each of said top wall and said bottom wall joined to each of said pair of sidewalls; and
at least one internal barrier coupled within said ventilated cover and displaced from said front wall in the first direction.

4. An electrical enclosure in accordance with claim 3, wherein said at least one internal barrier comprises:
an upper internal barrier coupled to said top wall and extending towards said bottom wall, said upper internal barrier including a plurality of ventilation openings; and
a substantially solid lower barrier displaced from said upper internal barrier in the first direction and coupled to said bottom wall, said substantially solid lower barrier extending between said bottom wall and said upper internal barrier.

5. An electrical enclosure in accordance with claim 4, wherein said at least one internal barrier further comprises a particulate barrier displaced from said substantially solid lower barrier in the first direction and coupled to each of said pair of sidewalls, said top wall, and said bottom wall, said particulate barrier including a plurality of ventilation openings.

6. An electrical enclosure in accordance with claim 1, wherein said arc shield assembly further comprises at least one closing mechanism, said at least one closing mechanism comprising:
a linkage arm coupled to said arc shield; and
a biasing member coupled to said linkage arm and configured to cause said arc shield to rotate to said second, closed position during an arc fault.

7. An electrical enclosure in accordance with claim 6, said arc shield assembly further comprises a pair of arc shield side retainer plates, wherein said biasing member and said pair of arc shield side retainer plates are configured to cooperate to retain said arc shield in said first, open position in the absence of an arc fault, and in said second, closed position during an arc fault.

8. An electrical enclosure in accordance with claim 7, wherein said arc shield assembly further comprises an arc shield locking mechanism, wherein said arc shield locking mechanism is configured to receive said arc shield and releasably retain said arc shield in said second, closed position.

9. A ventilation cover assembly configured to cover a ventilation aperture in an electrical enclosure, said ventilation cover assembly comprising:
a ventilated cover comprising:
a front wall including an upper portion and a lower portion, said lower portion including a plurality of ventilation openings;
a pair of sidewalls coupled to said front wall on opposite edges of said front wall and extending in a first direction perpendicular to said front wall; and
a top wall and a bottom wall joined to said front wall on opposite edges and extending in the first direction, each of said top wall and said bottom wall joined to each of said pair of sidewalls; and
at least one internal barrier coupled within said ventilated cover and displaced from said front wall in the first direction.

10. A ventilation cover assembly in accordance with claim 9, wherein said bottom wall includes a plurality of drainage openings defined therethrough.

11. A ventilation cover assembly in accordance with claim 9, wherein said at least one internal barrier further comprises an upper internal barrier coupled to said top wall and extending towards said bottom wall, said upper internal barrier including a plurality of ventilation openings.

12. A ventilation cover assembly in accordance with claim 11, wherein said at least one internal barrier comprises:
a substantially solid lower barrier coupled to said bottom wall, said substantially solid lower barrier extending between said bottom wall and said upper internal barrier.

13. A ventilation cover assembly in accordance with claim 12, wherein said at least one internal barrier further comprises a particulate barrier displaced from said substantially solid lower barrier in the first direction and coupled to each of said pair of sidewalls, said top wall, and said bottom wall, said particulate barrier including a plurality of ventilation openings.

14. A ventilation cover assembly in accordance with claim 13, wherein said at least one internal barrier and said ventilated cover are configured to define between said at least one internal barrier and said ventilated cover a curvelinear ventilation path.

15. A ventilation cover assembly in accordance with claim 14, wherein said substantially solid lower barrier is displaced from said upper internal barrier in the first direction to define a curvelinear second ventilation path therebetween.

16. An arc shield assembly for an electrical enclosure, said arc shield assembly comprising:
an arc shield rotatably coupled to the electrical enclosure and configured to rotate between a first, open position and a second, closed position, wherein said first, open position facilitates a flow of gasses through the electrical enclosure and said second, closed position inhibits a flow of gasses through the arc shield assembly;
a closing mechanism comprising:
a linkage arm coupled to said arc shield; and
a biasing member coupled to said linkage arm and configured to cause said arc shield to rotate to said second, closed position during an arc fault.

17. An arc shield assembly in accordance with claim 16, wherein said arc shield is substantially solid and is configured to inhibit gasses from passing through said arc shield.

18. An arc shield assembly in accordance with claim 17 further comprising a pair of arc shield side retainer plates, wherein said biasing member and said pair of arc shield side retainer plates are configured to cooperate to retain said arc shield in said first, open position in the absence of an arc fault, and in said second, closed position during an arc fault.

19. An arc shield assembly in accordance with claim 16 further comprising an arc shield locking mechanism, wherein said arc shield locking mechanism is configured to receive said arc shield and releasably retain said arc shield in said second, closed position.

20. A ventilation cover assembly in accordance with claim 16 further comprising an arc shield rotatably coupled to said ventilation cover assembly and configured to rotate between a first, open position and a second, closed position, wherein said first, open position facilitates a flow of gasses through said ventilation cover assembly and said second, closed position inhibits a flow of gasses through said ventilation cover assembly.
